(19) United States
(12) Patent Application Publication
(10) Pub. No.: US 2004/0197475 A1
(43) Pub. Date: Oct. 7, 2004

(54) Method for coating oxidizable materials with oxide containing layers

(76) Inventors: Oliver Stadel, Wendeburg (DE); Andrey R. Kaul, Moskau (RU); Oleg Yu Gorbenko, Moskau (RU)

Correspondence Address: SALTER & MICHAELSON, THE HERITAGE BUILDING, 321 SOUTH MAIN STREET, PROVIDENCE, RI, 029037128

(21) Appl. No.: 10/487,553

(22) PCT Filed: Aug. 13, 2002
(86) PCT No.: PCT/EP02/09070

(30) Foreign Application Priority Data
Aug. 27, 2001 (DE) 101 40 956.7

(51) Int. Cl. C23C 16/06

(52) U.S. Cl. 427/255.31

(57) ABSTRACT

The invention relates to a method for coating oxidizable materials with oxide-containing layers by chemical vapor deposition, using organometallic precursors in a reducing atmosphere. The reducing atmosphere used is a nitrogen-hydrogen compound, especially ammonia.

The invention relates to a method for coating oxidizable materials with oxide-containing layers, using a chemical vapour-phase deposition of metallo-organic precursors in a reducing atmosphere, in which at least one of the participants in the method contains oxygen.

In the production of superconductors, it is becoming more and more important not only to deposit the superconducting layers themselves in desired good qualities, but also to optimize the substructure of said superconducting layers.

There are frequently deposited directly onto textured nickel tapes first of all intermediate layers, onto which the highly superconductive layers are then applied subsequently in a further deposition process (not relevant in the context of the invention). The above-mentioned intermediate layers are preferably textured cerium oxide layers, i.e. CeO₂ layers. Layers of Yb₂O₃, Y₂O₃ and yttrium-stabilized zirconium oxide are also known from Dominic F. Lee et al, “Alternative buffer architectures for high critical current density YBCO superconducting deposits on rolling assisted biaxially-textured substrates”, in: Japanese Journal of Applied Physics 38 (1999) Part 2 No. 2B, pages 178-180, and from Ataru Ichinose et al, “Studies of the improvement in microstructure of Y₂O₃ buffer layers and its effect on YBa₂ Cu₃ ⁰7-x film growth”, in: Superconductor Science Technology 13 (2000), pages 1023-1028. Intermediate layers of LaCrO₃ or LaMnO₃ have also already been proposed by Oliver Stadel et al, “Continuous YBCO deposition onto moved tapes in liquid single source MOCVD systems”, in: Physica C341-348 (2000), pages 2477-2478. It is common to said layers that they are oxides. In addition, they have to be deposited onto nickel, i.e. an oxidizable material.

During the deposition process a number of auxiliary conditions must be satisfied in order to obtain a coating that meets the requirements in quality terms. Coatings by means of a chemical vapour-phase deposition have been proposed and also tested. Metallo-organic precursors with a highly sophisticated composition are used here, for example Cerium 2,2,6,6-tetramethylheptane-3,5-dione, which are in a hydrogen (H₂) or carbon monoxide (CO) atmosphere. The precursor gas is conveyed onto the heated substrate to be coated. On impact the chemical compound of the precursor decomposes, so that the layer of CeO₂ is then deposited during the chemical vapour-phase deposition; the remaining parts of the precursor are not required and are led off. Said layers showed an untextured polycrystalline structure under said conditions. The deposition of textured oxides onto textured nickel tapes by the methods of thermal evaporation and electron-beam evaporation is prior art. Said methods operate in the ultra-high vacuum range.

Other methods used (laser ablation, sputtering, sol gel etc.) encounter difficulties in supplying a sufficiently good layer quality for the production of the superconductor. Care must be taken in the coating process that no oxidation of the textured nickel tape takes place. This is achieved by the use of reducing hydrogen.

In EP 1 067 595 A2 a liquid precursor mixture (mixture of precursor compounds) is proposed for depositing a metal-containing multi-component material. The solvent-free mixture can be mixed prior to its deposition with a nitrogen-containing source. The precursor compounds are highly complex and expensive and the use of liquid precursor compounds is an additional complication in the process.

The coating methods tested in practice have the disadvantage that because of the auxiliary technical conditions a very low productivity is obtained with a simultaneously very high energy consumption, that the capital costs become very high, and that large areas of the substrate can be coated only with great difficulty. The quality of the intermediate layer obtained is despite this not adequate for the desired purpose in all cases.

The object of the invention is therefore to propose a process according to the preamble with which, at the lowest possible cost, an at least equally good layer can be obtained on oxidizable materials such as in particular textured nickel tapes.

Said object is achieved by the fact that one or more nitrogen-hydrogen compounds are used as the reducing atmosphere. It is particularly preferable if ammonia (NH₃) is used as the nitrogen-hydrogen compound.

The use of nitrogen-hydrogen compounds, in particular of ammonia, as reducing atmosphere for the desired purpose is surprising. The reducing gas used conventionally is always hydrogen, which is regularly available and is in any case always the choice if a reducing atmosphere is to be worked in; it is in any case not problematical from the standpoint of prior art. Carbon monoxide would have been possible as an alternative at best from a current standpoint.

Through the use of an ammonia atmosphere, however, a whole series of advantages can be achieved, which appear logical to the skilled man in retrospect, but were not obvious initially.

This applies more particularly to the safety measures required. Ammomia requires in contrast to hydrogen or carbon monoxide a far lower safety standard, since particularly as regards the auxiliary peripheral conditions to be considered here the reactivity (explosivity) is substantially less than that of hydrogen or carbon monoxide.

In addition, it has also been found, however, that in the coating process itself the undesirable introduction of carbon into the layer produced can easily be avoided, in stark contrast to a coating in a carbon monoxide or a hydrogen atmosphere. Hydrogen radicals are produced during the coating process through the breakdown of ammonia, and they apparently inhibit this.

Alternative atmospheres that have also not yet been considered for MOCVD, and offer similar advantages, are other nitrogen-hydrogen compounds such as hydrazine (N₂H₄), diimide (N₂H₂) and hydroxylamine (H₃NO). The breakdown process, although similar to that of ammonia, nevertheless takes place far more quickly, so that ammonia would be preferred on safety grounds. As in the case of ammonia, however, hydrogen radicals are formed, and said substances likewise make an epitaxial growth on textured nickel tapes possible. In particular hydrazine (N₂H₄) and diimide (N₂H₂) are therefore promising atmospheres to be used for particular applications, together in certain circumstances with hydroxylamine (H₃NO) and other nitrogen-hydrogen compounds that have a reducing effect.

It is found as a further advantage that nitrogen-hydrogen compounds and in particular ammonia are, in contrast to hydrogen, adsorbed only very slightly on the surface of the textured nickel tapes or the layers produced. In addition, an epitaxial crystallisation of the deposited layer in the low vacuum range is finally also made possible. It is therefore no longer necessary to operate in the ultra-high vacuum range as in the prior art. This reduces to a significant degree the cost of the plants and naturally also of the energy used by the plants, since an ultra-high vacuum no longer has to be generated. It is consequently also preferred to carry out the process according to the invention at an overall pressure of between 50 and 1×10⁵ Pascal, in particular an ammonia partial pressure of 5 to 1×10⁵ Pascal. The preferred temperatures for the substrate lie between 300 and 900° C., the temperatures for the substrate supply or the reactor jacketing should be about 600° C.

The process is preferably carried out with oxidizable materials that contain nickel, in particular textured nickel tapes or tapes of a nickel-based alloy, for example nickel alloyed with tungsten.

It is also possible, however, to use instead of textured nickel tapes other suitable substrates, for example ones that contain molybdenum or tungsten-alloyed nickel. Other materials such as steels or other metals are also possible. In the case of said materials a continuous oxidation during the coating process is prevented. A progressive oxidation of the material to be coated can, for example, seriously affect the layer adhesion.

The oxide-containing layers are preferably cerium oxides (CeO₂). Other oxide-containing layers can however also be deposited in similar form by means of a chemical vapour-phase deposition, for example LaCrO₃, LaMnO₃, or else quite generally perovskites or cubically stabilised ZrO₂ or R₂O₃, where R is chosen from the group Sc, Lu, Yb, Tm, Er, Y, Ho, Dy, Tb, Gd, Eu and Sm, and finally also solid solutions such as LaMnₓCr₁₋ₓO₃ etc.

It is in particular preferred for the deposition of cerium oxide layers that the metallo-organic precursors are cerium 2,2,6,6-tetramethylheptane-3,5-diones; other β-diketonates are however also possible. The latter can also be used as ligands for the provision of the metallo-organic precursors.

It is also possible, as a profitable area of use over and above the production of layers on textured nickel tapes or nickel films for the production of superconductors, to coat perovskitic oxygen membranes onto porous sintered metal material. Efforts are currently being made to deposit thin oxygen membranes on porous membranes by other methods, in order to close the pores of the latter and achieve a very high oxygen permeability. The method according to the invention could also be used with advantage in said efforts.

As regards the production of oxygen-conducting ceramic membranes, it is still completely unknown to date to use a reducing atmosphere in MOCVD processes. In this case, therefore, the use of a hydrogen (H₂) atmosphere would by itself be an advance over the prior art, particularly as, in contrast to superconductors, the layers produced do not require a pronounced texture.

In other areas also it could be profitable to coat easily oxidizable materials with oxides by means of said metallo-organic CVD method (MOCVD), and to use an ammonia (NH₃) atmosphere for this, in particular if it is also advantageous that H radicals result from the breakdown of the ammonia (NH₃).

An embodiment of the invention will be explained in detail below by means of the drawing, in which

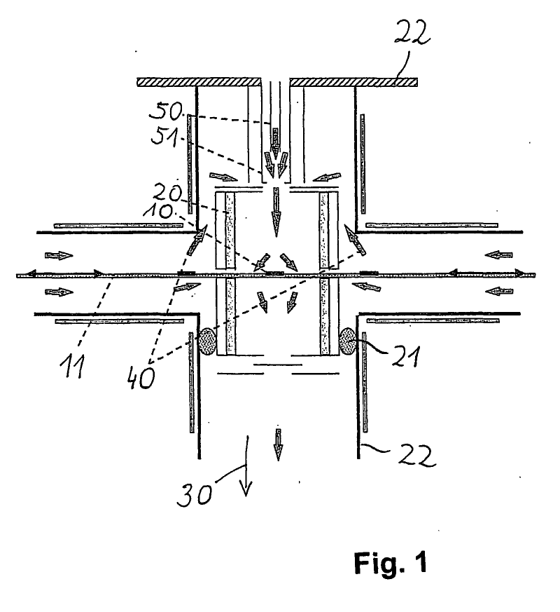

FIG. 1 is a diagrammatic representation of the production of a coating.

In FIG. 1 the diagrammatic layout of a coating reactor is to be seen. A substrate 10 is to be coated, which is located on a substrate holder 11. The substrate holder 11 with the substrate 10 is here shown on a horizontal surface at right angles to the image plane. The substrate holder 11 can be displaced in order to coat successively various substrates 10 lying on it.

To this end it is pushed through a cylindrical reactor furnace 2. The latter is to be seen here in a section parallel with the axis, the substrate 10 is located in the drawing precisely in the centre of the cylindrical reactor furnace 20.

The gases contained in the cylindrical reactor furnace 20 can be sucked out of the latter by means of a pump 30 in a downwards direction in the drawing. The cylindrical reactor furnace is at the same time sealed against the walls of the overall reactor 22 by means of a seal 21 in such a way that the pump 30 is not able to suck off any gases from the side.

In order to produce an atmosphere inside the cylindrical reactor furnace 20, purge gases 40 are fed parallel with the substrate holder 11 in measured quantities from left and right; according to the invention ammonia (NH₃) is involved, in certain cases ammonia and additionally nitrogen. Said gases flow from left and right towards the centre and then from above into the cylindrical reactor furnace 20. The purge gases 40 and their flow direction are indicated by vector arrows.

The precursor is fed from above via a precursor nozzle 50 by means of a separate feed. It is to be recognised by a thicker vector arrow. The precursor mingles in the feed area and in an outer coaxial nozzle 51 with the purge gases 40, which form the major part of the reducing atmosphere produced. This means that the reducing atmosphere of ammonia (NH₃) containing smaller components of the metallo-organic precursor gas is located in the main in the area of the substrate 10 inside the cylindrical reactor furnace 20 on the substrate holder 11. The desired components, in particular therefore CeO₂, are deposited on the substrate 10 out of the precursor and the remaining gases are then drawn off by the pump 30 together with the purge gas.

It is critical that as little oxygen as possible must be present during the coating process, in order not to disturb the deposition reaction. As discussed above, attempts are made, or consideration given, to achieving this with hydrogen (H₂) or carbon monoxide (CO) atmospheres. Both atmospheres have the disadvantage of being extremely dangerous and/or poisonous. In addition, both atmospheres from the prior art in the final analysis attack the textured surface of the nickel tapes and thus interfere with the desired deposition of the cerium oxide.

Both problems are completely solved by the fact that an entirely novel atmosphere, namely an ammonia (NH₃) atmosphere, is used.

Firstly, ammonia is far less dangerous or poisonous than H₂ or CO and for this reason alone represents an advantage. In addition, it also has the advantage—and this has been demonstrated—that it does not attack the textured nickel surface during the coating. There is a further side effect, namely that due to the free hydrocarbon radicals of ammonia that are produced, any impurities that still exist in the form of exceptionally undesirable oxygen atoms are removed; this also applies to impurities in the form of carbon atoms. The inclusion of the latter in the layer to be deposited can thereby be prevented. Volatile hydrocarbons are formed, for example methane and water vapour, both of which are also removed by the pumping off.

Particularly preferably a pressure of between 500 and 1000 Pascal and an ammonia partial pressure of between 60 and 1000 Pascal are used with a substrate temperature of 800 to 900 degrees Celsius. Slightly more extensive coating conditions are however conceivable.

It was found during the practical tests carried out that the cerium oxide (CeO₂) layer produced in this way is textured, namely in accordance with the texturing of the substrate. No carbon was able to be detected in said layers by means of wavelength-dispersive x-ray analysis (WDX).

The textured CeO₂ layers produced on the nickel tapes in this way are suitable as intermediate layers in particular for the high-temperature superconductor YBCO. Without a textured intermediate layer it is impossible to manufacture good superconducting layers. Only said quality of the layers will make practical use in high-temperature superconductor technology possible. It is still not possible today, using the atmospheres employed to date in the prior art, to produce textured intermediate layers of the required quality by the MOCVD process.

It is however also possible to produce oxides for other purposes by MOCVD (metallo-organic chemical vapour-phase deposition) using ammonia as reducing atmosphere. The depositing of other oxides has also become possible by testing, and a deposition of cerium oxides on YSZ (100) monocrystals has also already been tried out in practice.

### Lift of Reference Symbols

10 substrate

11 substrate holder

20 cylindrical reactor furnace

21 seal

22 overall reactor

30 pump

40 purge gases

50 precursor nozzle

51 outer coaxial nozzle

1. Method for coating oxidizable materials with oxide-containing layers, using a chemical vapour-phase deposition of metallo-organic precursors in a reducing atmosphere, in which at least one of the participants in the method contains oxygen,
characterised in that
one or more nitrogen-hydrogen compounds are used as the reducing atmosphere.

2. Method according to claim 1,
characterised in that
ammonia (NH₃) is used as nitrogen-hydrogen compound.

3. Method according to claim 1,
characterised in that
hydrazine (N₂H₄), diimide (N₂H₂) and/or hydroxylamine (H₃NO) are used as nitrogen-hydrogen compound.

4. Method according to claim 1,
characterised in that
the oxidizable materials contain metals.

5. Method according to claim 4,
characterised in that
the oxidizable materials contain nickel.

6. Method according to claim 5,
characterised in that
the oxidizable materials are textured nickel tapes or tapes of a nickel-based alloy.

7. Method according to claim 1,
characterised in that
the oxide-containing layers contain cerium oxide (CeO₂).

8. Method according to claim 11,
characterised in that
β-diketonates, in particular Ce 2,2,6,6-tetramethylheptane-3,5-dione (Ce(thd)₄), are used as metallo-organic precursors.

9. Method according to claim 1.
characterised in that
the oxide-containing layers contain rare earth oxides R₂₀ ₃ or zirconium oxide stabilised cubically with R or E, with R from the group Sc, Lu, Yb, Tm, Er, Y, Ho, Dy, Th, Gd, Eu and Sm and with E from the group Be, Mg, Ca, Sr, Ba, Ce, or LaCrO₃ or LaMnO₃ or LaMnO₃ Cr₁₋ₓO₃ or perovskites.

10. Method according to claim 1,
characterised in that
the chemical vapour-phase deposition takes place at a pressure of between 50 and 1×10⁵ Pascal, in particular at an ammonia partial pressure of 5 to 1×10⁵ Pascal.

11. Method according to claim 1,
characterised in that
the chemical vapour-phase deposition takes place at a temperature of the substrate of between 300 and 900° C.
